(19) United States
(12) Patent Application Publication
(10) Pub. No.: US 2019/0067589 A1
(43) Pub. Date: Feb. 28, 2019

(54) ORGANIC ELECTROLUMINESCENCE DEVICE

(71) Applicant: SAMSUNG DISPLAY CO., LTD., Yongin-si (KR)

(72) Inventors: Seokgyu YOON, Hwaseong-si (KR); Shuri SATO, Tsurumiku (JP); Junta FUCHIWAKI, Tsurumiku (JP); Yoshimasa FUJITA, Tsurumiku (JP)

(21) Appl. No.: 16/106,520

(22) Filed: Aug. 21, 2018

(30) Foreign Application Priority Data
Aug. 25, 2017 (KR) 10-2017-0108219

(51) Int. Cl. H01L 51/00; H01L 51/50

(52) U.S. Cl. CPC H01L 51/0061; H01L 51/5092; H01L 51/0055; H01L 51/0058; H01L 51/0072; H01L 51/0067; H01L 51/0054; H01L 51/5016; H01L 2251/552; H01L 51/5056; H01L 51/5088; H01L 51/5096; H01L 2251/558; H01L 51/5072; H01L 51/5004

(57) ABSTRACT

An organic electroluminescence device including a first electrode; a hole transport region on the first electrode; a light emitting layer on the hole transport region; an electron transport region on the light emitting layer; and a second electrode on the electron transport region, wherein the light emitting layer includes a first compound satisfying Formula 1 below and a second compound satisfying Formula 2 below, and the first compound has a full width at half maximum of 60 nm or less:

V2>V1 [Formula 1]

K1>1.1×K2. [Formula 2]

### CROSS-REFERENCE TO RELATED APPLICATIONS

Korean Patent Application No. 10-2017-0108219, filed on Aug. 25, 2017, in the Korean Intellectual Property Office, and entitled: “Organic Electroluminescence Device,” is incorporated by reference herein in its entirety.

### BACKGROUND

### 1. Field

Embodiments relate to an organic electroluminescence device.

### 2. Description of the Related Art

As an image display device, an organic electroluminescence display device using an organic electroluminescence device has been actively developed. An organic electroluminescence display device is different from a liquid crystal display device, and the like in that it is a self-luminescence display device which realizes display by recombining holes and electrons injected from a first electrode and a second electrode in a light emitting layer to emit a light emitting material which is an organic compound included in the light emitting layer.

An organic electroluminescence device may include an organic device composed of a first electrode, a hole transport layer disposed on the first electrode, a light emitting layer disposed on the hole transport layer, an electron transport layer disposed on the light emitting layer, and a second electrode disposed on the electron transport layer. From the first electrode, a hole is injected, and the injected hole moves through the hole transport layer to be injected to the light emitting layer. From the second electrode, an electron is injected, and the injected electron moves through the electron transport layer to be injected to the light emitting layer. The hole and the electron both injected to the light emitting layer are recombined to generate an exciton in the light emitting layer. An organic electroluminescence device emits light using light generated when the exciton falls to a ground state again.

### SUMMARY

Embodiments are directed to an organic electroluminescence device.

The embodiments may be realized by providing an organic electroluminescence device including a first electrode; a hole transport region provided on the first electrode; a light emitting layer provided on the hole transport region; an electron transport region provided on the light emitting layer; and a second electrode provided on the electron transport region, wherein the light emitting layer includes a first compound satisfying Formula 1 below and a second compound satisfying Formula 2 below, and the first compound has a full width at half maximum of 60 nm or less:

V2>V1 [Formula 1]

wherein, in Formula 1, V1 is a sum of non-radiative transition rates transitioning from an n^{th} triplet excited state to a lower order triplet excited state including the lowest triplet excited state, and V2 is a reverse intersystem transition rate transitioning from an n^{th} triplet excited state to a singlet excited state adjacent to the n^{th} triplet excited state, where n is an integer of 2 or greater; and,

K1>1.1×K2 [Formula 2]

wherein, in Formula 2, K1 is an energy level of a lowest singlet excited state of the second compound, and K2 is an energy level of a lowest triplet excited state of the second compound.

The light emitting layer may include a host and a dopant, the host may include the first compound, and the dopant may include the second compound.

The dopant may be a fluorescent dopant.

A weight percentage of the dopant based on a total weight of the host and the dopant may be 0.01 wt % to 10 wt %.

The host may include a first host and a second host, the first host may be the first compound, and an energy level of the lowest triplet excited state of the second host may be higher than an energy level of the lowest singlet excited state of the first compound.

The host may include a first host and a second host, the first host may be the first compound, and an energy level of the lowest singlet excited state of the second host may be lower than an energy level of the lowest singlet excited state of the first compound.

The first compound may satisfy Formula 1-1 below:

V2≥0.1×V1 [Formula 1-1]

wherein, in Formula 1-1, V1 and V2 are defined the same as those of Formula 1.

V1 may be 1×10⁹ s⁻¹ or less.

### BRIEF DESCRIPTION OF THE DRAWINGS

Features will be apparent to those of skill in the art by describing in detail exemplary embodiments with reference to the attached drawings in which:

FIG. 1 illustrates a sectional view schematically showing an organic electroluminescence device according to an embodiment of the present disclosure;

FIG. 2 illustrates a sectional view schematically showing an organic electroluminescence device according to an embodiment of the present disclosure;

FIG. 3 illustrates an energy diagram of a first compound included in an organic electroluminescence device according to an embodiment of the present disclosure;

FIG. 4 illustrates an energy diagram of a second compound included in an organic electroluminescence device according to an embodiment of the present disclosure;

FIG. 5 illustrates a view of the energy transfer and light emitting mechanism of a light emitting layer of an organic electroluminescence device according to an embodiment of the present disclosure;

FIG. 6 illustrates a view of the energy transfer and light emitting mechanism of a light emitting layer of an organic electroluminescence device according to an embodiment of the present disclosure;

FIG. 7 illustrates a view of the energy transfer and light emitting mechanism of a light emitting layer of an organic electroluminescence device according to an embodiment of the present disclosure;

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration.

In describing each drawing, similar reference numerals were used for similar elements. It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. The terms of a singular form may include plural forms unless the context clearly indicates otherwise.

In this application, terms, e.g., “include,” “comprise,” or “have” are intended to designate features, numbers, steps, operations, elements, parts, or combinations thereof described in the specifications of the present disclosure but not to exclude the possibility of the presence or the addition of one or more other features, numbers, steps, operations, elements, parts, or combinations thereof. It will also be understood that when a portion, such as a layer, a film, a region, and a plate is referred to as being “on” another portion, it can be “directly on” the other portion, or one or more intervening portions may also be present. On the other hand, it will be understood that when a portion, such as a layer, a film, a region, and a plate is referred to as being “under” another portion, it can be “directly under”, or one or more intervening portions may also be present. As used herein, the term “or” is not an exclusive term, and has the same meaning as “and/or.”

Hereinafter, an organic electroluminescence device according to an embodiment of the present disclosure will be described.

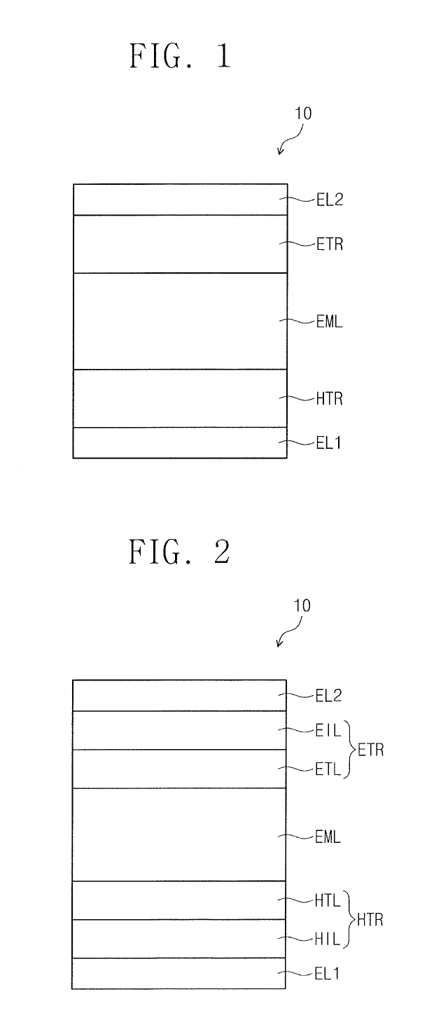

FIG. 1 illustrates a sectional view schematically showing an organic electroluminescence device according to an embodiment of the present disclosure. FIG. 2 illustrates a sectional view schematically showing an organic electroluminescence device according to an embodiment of the present disclosure.

Referring to FIGS. 1 and 2, an organic electroluminescence device 10 according to an embodiment of the present disclosure may include a first electrode EL1, a hole transport region HTR, a light emitting layer EML, an electron transport region ETR, and a second electrode EL2.

The first electrode EL1 has conductivity. The first electrode may be a pixel electrode or a positive electrode. The first electrode EL1 may be a transmissive electrode, a transflective electrode, or a reflective electrode. When the first electrode EL1 is a transmissive electrode, the first electrode may include a transparent metal oxide, e.g., indium tin oxide (ITO), indium zinc oxide (IZO), zinc oxide (ZnO), indium tin zinc oxide (ITZO), and the like. When the first electrode EL1 is a transflective electrode or a reflective electrode, the first electrode EL1 may include, e.g., Ag, Mg, Cu, Al, Pt, Pd, Au, Ni, Nd, Ir, Cr, Li, Ca, LiF/Ca, LiF/Al, Mo, Ti, or a compound, or a mixture thereof (for example, a mixture of Ag and Mg). In an implementation, the first electrode EL1 may be of a multilayer structure including a reflective film or a transflective film, both formed of the above materials, and a transparent conductive film formed of indium tin oxide (ITO), indium zinc oxide (IZO), zinc oxide (ZnO), indium tin zinc oxide (ITZO), and the like.

The hole transport region HTR may be provided on the first electrode EL1. The hole transport region HTR may include at least one of a hole injection layer HIL, a hole transport layer HTL, a hole buffer layer, or an electron blocking layer. The thickness of the hole transport region HTR may be, for example, of about 1,000 Å to 1,500 Å.

The hole transport region HTR may have a single layer structure having a single layer formed of a single material, a single layer structure having a single layer formed of a plurality of different materials, or a multilayer structure having a plurality of layers formed of a plurality of different materials.

In an implementation, the hole transport region HTR may have a single layer structure having a single layer of the hole injection layer HIL or the hole transport layer HTL, or have a single layer structure having a single layer formed of a hole injection material and a hole transport material. In an implementation, the hole transport region HTR may have a single layer structure having a single layer formed of a plurality of different materials, or have a structure of a hole injection layer HIL/a hole transport layer HTL, a hole injection layer HIL/a hole transport layer HTL/a hole buffer layer, a hole injection layer HIL/a hole buffer layer, a hole transport layer HTL/a hole buffer layer, or a hole injection layer HIL/a hole transport layer HTL/an electron blocking layer, sequentially laminated from the first electrode EL.

The hole transport region HTR may be provided by various methods such as vacuum deposition, spin coating, casting, Langmuir-Blodgett (LB), inkjet printing, laser printing, laser induced thermal imaging (LITI).

The hole injection layer HIL may include, e.g., a phthalocyanine compound such as copper phthalocyanine; N,N′-diphenyl-N,N′-bis-[4-(phenyl-m-tolyl-amino)-phenyl]-biphenyl-4,4′-diamine (DNTPD), 4,4′,4″-tris(3-methylphenylphenylamino) triphenylamine (m-MTDATA), 4,4′4″-Tris(N,N-diphenylamino)triphenylamine (TDATA), 4,4′,4″-tris{N,-(2-naphthyl)-N-phenylamino}-triphenylamine (2-TNATA), Poly(3,4-ethylenedioxythiophene)/Poly(4-styrenesulfonate) (PEDOT/PSS), Polyaniline/Dodecylbenzenesulfonic acid (PANI/DBSA), Polyaniline/Camphor sulfonicacid PANI/CSA), (Polyaniline)/Poly(4-styrenesulfonate) (PANI/PSS), N,N′-di(naphthalene-1-yl)-N,N′-diplienyl-benzidine (NPB), a polyether ketone (TPAPEK) including triphenylamine, 4-Isopropyl-4′-methyldiphenyliodonium Tetrakis(pentafluorophenyl)borate], dipyrazino[2,3-f:2′,3′-h]quinoxaline-2,3,6,7,10,11-hexacarbonitrile (HAT-CN), and the like.

The hole transport layer HTL may include, e.g., a carbazole-based derivative such as N-phenylcarbazole and polyvinylcarbazole, a fluorine-based derivative, a triphenylamine-based derivative such as N,N′-bis(3-methylphenyl)-N,N′-diphenyl-[1,1-biphenyl]-4,4′-diamine (TPD) and 4,4′,4″-tris(N-carbazolyl)triphenylamine (TCTA). N,N′-di(naphthalene-1-yl)-N,N′-diplienyl-benzidine (NPB), 4,4′-Cyclohexylidene bis[N,N-bis(4-methylphenyl)benzenamine] (TAPC), 4,4′-Bis[N,N′-(3-tolyl)amino]-3,3′-dimethylbiphenyl (HMTPD), and the like.

The thickness of the hole transport region HTR may be about 100 Å to about 10,000 Å, e.g., about 100 Å to about 1,000 Å. When the hole transport region HTR includes both the hole injection layer HIL and the hole transport layer HTL, the thickness of the hole injection layer HIL may be about 100 Å to about 10,000 Å, e.g., about 100 Å to 1,000 Å, and the thickness of the hole transport layer HTL may be about 30 Å to about 1,000 Å. When the thicknesses of the hole transport region HTR, the hole injection layer HIL, and the hole transport layer HTL satisfy the above-described ranges, a satisfactory hole transport characteristic may be obtained without a substantial increase in driving voltage.

The hole transport region HTR may further include a charge generating material to improve conductivity in addition to the above-mentioned materials. The charge generating material may be uniformly or non-uniformly dispersed in the hole transport region HTR. The charge generating material may be, e.g., a p-dopant. In an implementation, the p-dopant may be, e.g., one of a quinone derivative, a metal oxide, or a compound containing a cyano group. In an implementation, the p-dopant may include, e.g., a quinone derivative such as tetracyanoquinodimethane (TCNQ) and 2,3,5,6-tetrafluoro-tetracyanoquinodimethane (F4-TCNQ), and a metal oxide such as a tungsten oxide and a molybdenum oxide.

As described above, the hole transport region HTR may further include at least one of a hole buffer layer and an electron blocking layer in addition to the hole injection layer HIL and the hole transport layer HTL. The hole buffer layer may increase the light emission efficiency by compensating the resonance distance according to the wavelength of light emitted from the light emitting layer EML. As a material to be included in the hole buffer layer, a material which may be included in the hole transport region HTR may be used. The electron blocking layer is a layer which serves to prevent an electron from being injected from the electron transport region ETR to the hole transport region HTR.

The light emitting layer EML may be provided on the hole transport region HTR. The thickness of the light emitting layer EML may be, e.g., of about 100 Å to about 300 Å. In an implementation, the light emitting layer EML may have a single layer structure having a single layer formed of a single material, a single layer structure having a single layer formed of a plurality of different materials, or a multilayer structure having a plurality of layers formed of a plurality of different materials.

The light emitting layer EML may include a first compound and a second compound.

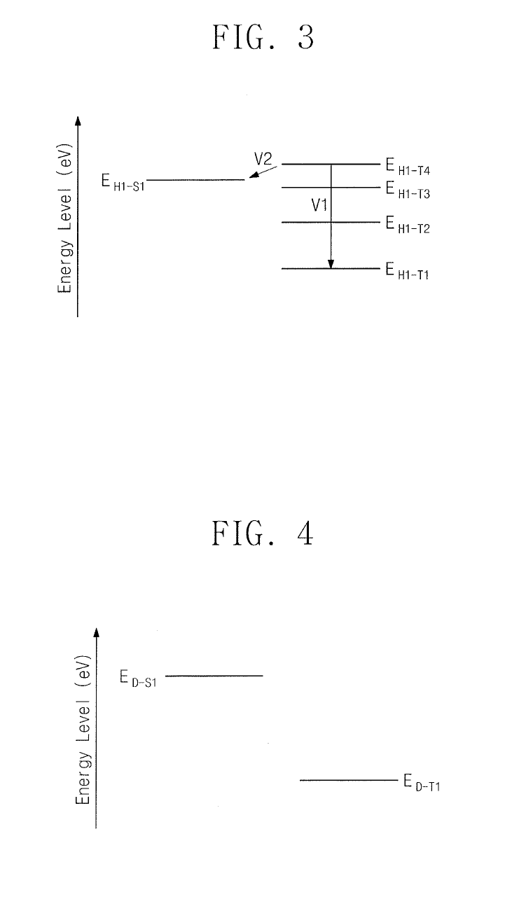

FIG. 3 illustrates an energy diagram of the first compound included in the organic electroluminescence device according to an embodiment of the present disclosure.

In an implementation, referring to FIG. 3, the first compound may be a compound satisfying Formula 1 below.

V2>V1 [Formula 1]

In Formula 1, V1 is a sum of the non-radiative transition rates transitioning from an n^{th} triplet excited state to a lower order triplet excited state including the lowest triplet excited state, and V2 is a reverse intersystem transition rate transitioning from an n^{th} triplet excited state to a singlet excited state adjacent to the n^{th} triplet excited state where n is an integer of 2 or greater.

For example, the first compound may be a compound of which the reverse intersystem crossing rate transitioning from the n^{th} triplet excited state to a singlet excited state adjacent to the n^{th} triplet excited state is higher than the non-reactive deactivation rate from the n^{th} triplet excited state to the lowest triplet excited state.

In the present specification, “reverse intersystem crossing” may mean transitioning from a triplet state to a singlet state.

FIG. 3 exemplarily illustrates a case in which n is 4 in Formula 1. In FIG. 3, the transition rate V2 transiting from a fourth triplet excited state (E_{H1-T4}) to a singlet excited state (E_{H1-S1}) adjacent to the fourth triplet excited state (E_{H1-T4}) is higher than the transition rate V1 transitioning from the fourth triplet excited state (E_{H1-T4}) to a lowest triplet excited state (E_{H1-T1}), the first compound has a higher probability of the exciton to be transitioned from the fourth triplet excited state (E_{H1-T4}) to the adjacent singlet excited state (E_{H1-S1}) than of an exciton to be transitioned from the fourth triplet excited state (E_{H1-T4}) to triplet excited states E_{H1-T3}, E_{H1-T2}, and E_{H1-T1} which have lower energy levels than the fourth triplet excited state (E_{H1-T4}).

In an implementation, as illustrated in FIG. 3, reverse intersystem crossing may transition from the fourth triplet excited state (E_{H1-T4}) to the lowest singlet excited state (E_{H1-S1}). In an implementation, V2 of Formula 1 may mean a transition rate from a fifth triplet excited state (when n is 5 in Formula 1) to a third singlet excited state. For example, an object of reverse intersystem crossing may be suitable as long as n is 2 or greater in Formula 1.

V2 of Formula 1 may be a transition rate from the third triplet excited state (E_{H1-T3}) to the singlet excited state (E_{H1-S1}) which is adjacent to the third triplet excited state (E_{H1-T3}) and has a high energy level. For example, in the definition of V2, the singlet excited state adjacent to the n^{th} triplet excited state may have a higher or lower energy level than the n^{th} triplet excited state. In the definition of V2, when the energy level of the singlet excited state adjacent to the n^{th} triplet excited state is higher than the energy level of the n^{th} triplet excited state, the smaller the energy gap, the better.

In an implementation, V1 may be 1×10⁹ s⁻¹ or less. For example, V1 may be 1×10⁹ s⁻¹ or greater and 1×10⁹ s⁻¹ or less. In an implementation, the transition rate from the fourth triplet excited state (E_{H1-T4}) to the lowest triplet excited state (E_{H1-T1}) may be 1×10⁹ s⁻¹ or less. When V1 of Formula 1 has a value as small as 1×10⁹ s⁻¹ or less, it means that the thermal deactivation rate of a triplet excited state is slow, and thus the probability of reverse intersystem crossing from the triplet excited state to the adjacent singlet excited state may increase.

The first compound may be one satisfying Formula 1-1 below.

V2≥0.1×V1 [Formula 1-1]

In Formula 1-1. V1 and V2 are the same as described above.

For example, the first compound may be a compound of which the reverse intersystem crossing rate transitioning from an n^{th} triplet excited state to a singlet excited state adjacent to the n^{th} triplet excited state is 0.1 times higher than the non-reactive deactivation rate from the n^{th} triplet excited state to the lowest triplet excited state. The larger V2 is, the better as long as V2 is, e.g., 0.1 times or greater than V1. In an implementation, V2 may be, e.g., 0.2 times greater than V1. In an implementation, the first compound may be such that V2 is, e.g., 0.1 times to 20 times greater than V1. In an implementation, the first compound may have, e.g., a full width at half maximum of 60 nm or less. When the first compounds has a full width at half maximum satisfying the above condition, the energy transfer from the first compound to the second compound is possible without energy loss, and as a result, an organic electroluminescence device having high efficiency may be realized.

FIG. 4 illustrates an energy diagram of the second compound included in an organic electroluminescence device according to an embodiment of the present disclosure. In an implementation, referring to FIG. 4, the second compound may be a compound satisfying Formula 2 below.

K1>1.1×K2 [Formula 2]

In Formula 2, K1 is an energy level of the lowest singlet excited state (E_{D-S1}) of the second compound, and K2 is an energy level of the lowest triplet excited state (E_{D-T1}) of the second compound.

When the first compound has a full width at half maximum of 60 nm or less and satisfies Formula 1, and the second compound satisfies Formula 2, in the light emitting layer EML of FIG. 1, an exciton located in a higher triplet excited state (E_{H1-T4}) of the first compound may be moved to the adjacent singlet excited state (E_{H1-S1}), and the moved exciton and a exciton located in the singlet excited state from the beginning may be moved to the lowest singlet excited state (E_{D-S1}) of the second compound and fall to a ground state (E_{D-S0}) to emit light.

For example, when the first compound satisfies Formula 1, an exciton in a higher triplet excited state may be moved to an adjacent singlet excited state. When the first compound has a full width at half maximum of 60 nm or less and the second compound satisfies Formula 2, the exciton moved from the triplet excited state to the single excited state of the first compound and an exciton located in the singlet excited state from the beginning may be moved to the lowest singlet excited state (E_{D-S1}) of the second compound without energy loss and may fall to the ground state (E_{D-S0}) to emit light.

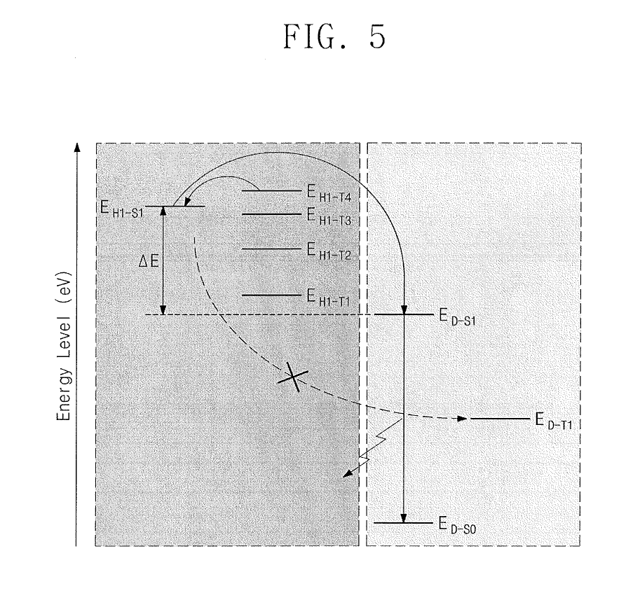

FIG. 5 illustrates a view of the energy transfer and light emitting mechanism of a light emitting layer of an organic electroluminescence device according to an embodiment of the present disclosure.

In an implementation, referring to FIG. 5, the first compound and the second compound may have a relationship satisfying Formula 3 below.

|Q1−Q2|≤1.0 eV [Formula 3]

In Formula 3, Q1 is the energy level of a singlet excited state most adjacent to an n^{th} triplet excited state of the first compound, and Q2 is the energy level of the lowest singlet excited state (E_{D-S1}) of the second compound. E of FIG. 5 corresponds to |Q1−Q2| of Formula 3.

When the second compound satisfies Formula 2 and the relationship of the first compound and the second compound satisfies Formula 3, an exciton moved from the triplet excited state to the singlet excited state of the first compound and an exciton located in the singlet excited state from the beginning may be prevented from moving to the lowest triplet excited state (E_{D-T1}) of the second compound, but may be moved to the lowest singlet excited state (E_{D-S1}) of the second compound to fall to the ground state (E_{D-S0}) to emit light. For example, by using a second compound the lowest triplet excited state and the lowest singlet excited state of which have comparatively large energy gaps, and by designing an energy gap of the singlet excited state of the first compound and an energy gap of a singlet excited state of the second compound relatively small, excitons collected at the energy level of the singlet excited state of the first compound may rapidly move to the lowest singlet excited state of the second compound to emit fluorescent light.

As a result, an organic electroluminescence device according to an embodiment of the present disclosure may realize high efficiency by using the movement of an exciton (energy) from a higher triplet state to a singlet state and may also realize long life by emitting light in the second compound which has a relatively low energy level.

Referring back to FIG. 1, the light emitting layer EML may include a host and a dopant. In an implementation, the host may include the first compound, and the dopant may include the second compound. The dopant may be a fluorescent dopant emitting light according to a fluorescent light emitting mechanism.

In an implementation, the amount, e.g., weight percentage, of the dopant, based on the total weight percentage of the host and the dopant, may be, e.g., 0.01 wt % to 10 wt %. Maintaining the amount of the dopant at 0.01 wt % or greater may help ensure the ability to control the doping concentration such that the characteristic deviation among devices may be avoided. Maintaining the amount of the dopant at 10 wt % or less may help ensure that the distance between dopants adjacent to each other is not too close, thereby reducing the possibility of efficiency loss due to mutual quench.

In an implementation, the light emitting layer EML may include two or more kinds of hosts. In an implementation, the light emitting layer EML may include a first host and a second host, and the first host may be the first compound. In an implementation, the host may include a first host and a second host, and in the light emitting layer, the content (e.g., weight percentage) of the second host may be larger than that of the first host.

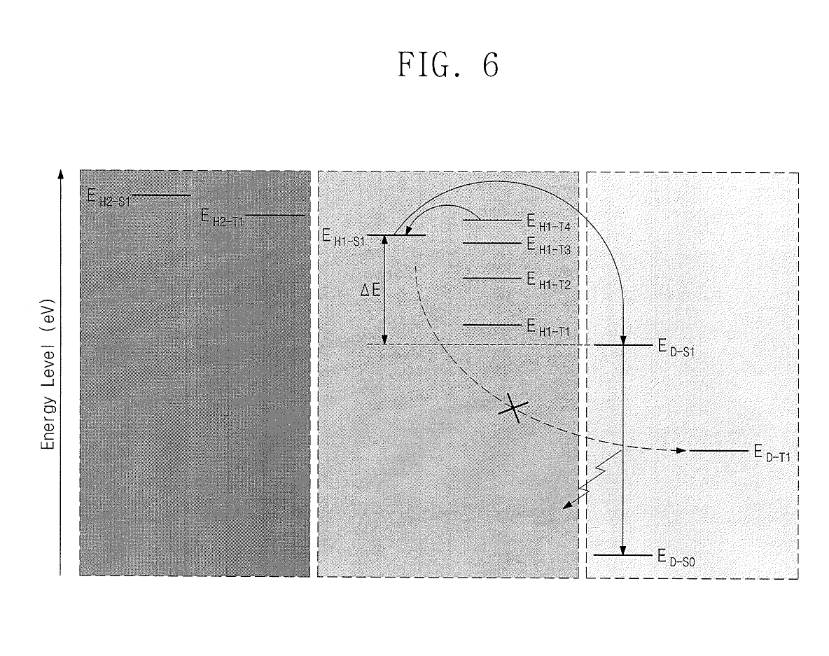

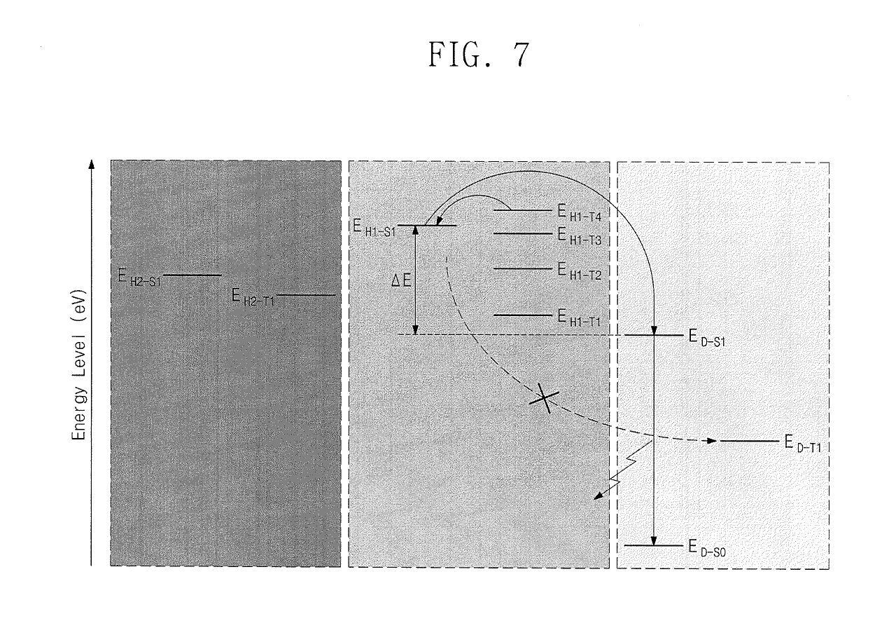

FIG. 6 illustrates a view of the energy transfer and light emitting mechanism of a light emitting layer of an organic electroluminescence device according to an embodiment of the present disclosure. FIG. 7 illustrates a view of the energy transfer and light emitting mechanism of a light emitting layer of an organic electroluminescence device according to an embodiment of the present disclosure.

In an implementation, referring to FIG. 6, the second host may be such that an energy level of the lowest triplet excited state (E_{H2-T1}) thereof may be higher than the energy level of the lowest singlet excited state (E_{H1-S1}) of the first compound which is the first host. In an implementation, referring to FIG. 7, the second host may be such that an energy level of the lowest singlet excited state (E_{H2-S1}) thereof may be lower than the energy level of the lowest singlet excited state (E_{H1-S1}) of the first compound which is the first host. For example, as the second host, one having a higher energy level than the energy level of the first host may be used, and one having a lower energy level than the energy level of the first host may be used.

By including the second host, it becomes possible to make the first compound (which is the first host) distant from the second compound (which is the dopant). Thus, it is possible to reduce or prevent a triplet exciton of the first compound from being deactivated to a triplet exciton of the second compound such that the probability of the triplet exciton being lost in a path other than light emission is reduced, and as a result, the organic electroluminescence device may have higher efficiency.

Meanwhile, an organic electroluminescence device according to an embodiment of the present disclosure may have a very short time for an exciton to stay in a triplet excited state (the reverse intersystem transition rate from a triplet excited state to a singlet excited state is high), and therefore, as illustrated in FIG. 7, even if the second host having a low energy level is used, it is possible to realize long life without loss in terms of efficiency. In an implementation, an organic electroluminescence device according to the present disclosure may include only a first host, not a second host, in which case it is possible to realize an organic electroluminescence device having even longer life.

Each of the first compound and the second compound may have 70% or greater of photoluminescence quantum yield (PLQY). Thus, it is possible to realize an organic electroluminescence device having even higher efficiency.

In an implementation, each of the first compound and the second compound may exhibit light emitting life of 0.9 μs or less. In this case, it is possible to minimize or prevent the roll-off reduction problem in the high luminance and to realize an organic electroluminescence device having even higher efficiency and longer life.

In an implementation, the first compound may be, e.g., a compound of the following Compound Group 1. In an implementation, the first compound may be a suitable compound that has a full width at half maximum of 60 nm or less and satisfies Formula 1.

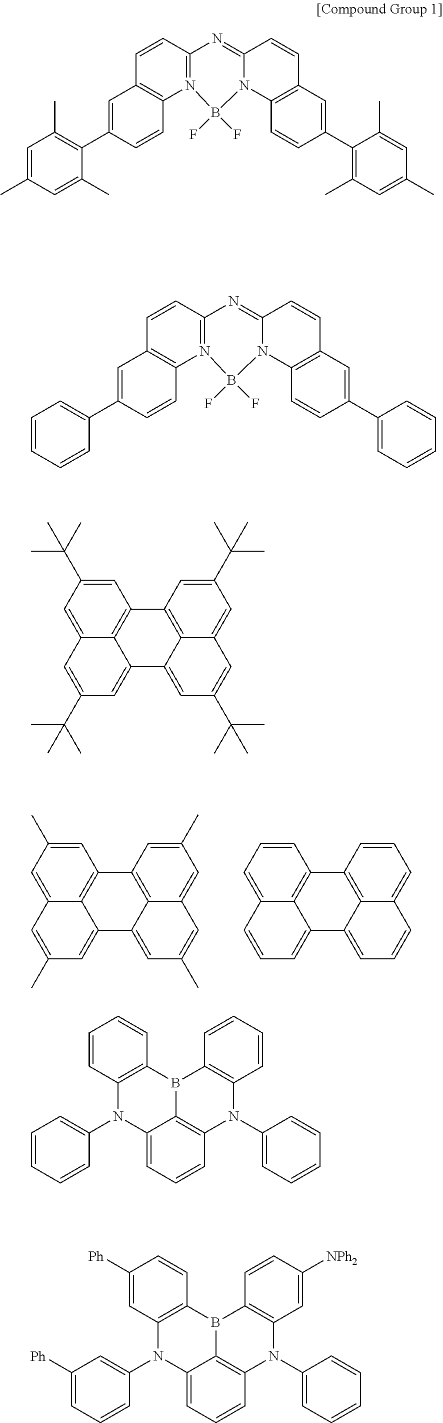

In an implementation, the second compound may be, e.g., a compound of the following Compound Group 2. In an implementation, the second compound may be a suitable compound that satisfies Formula 2.

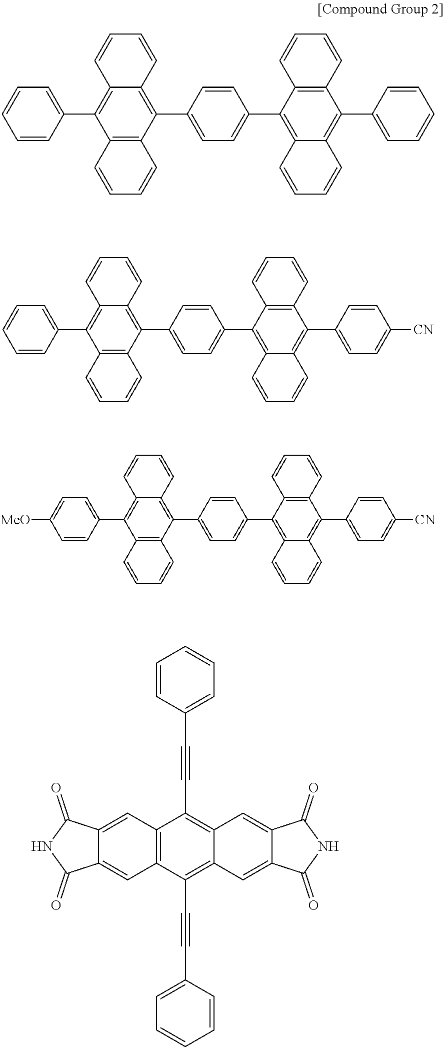

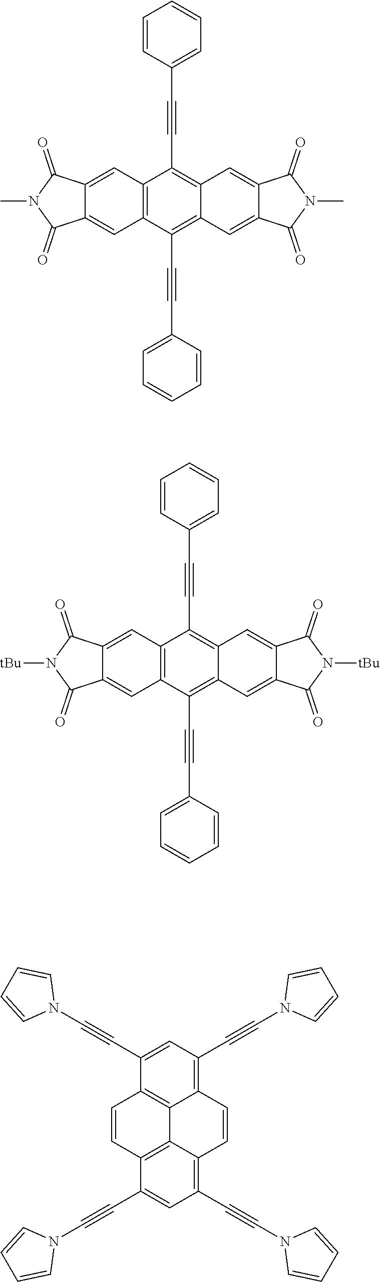

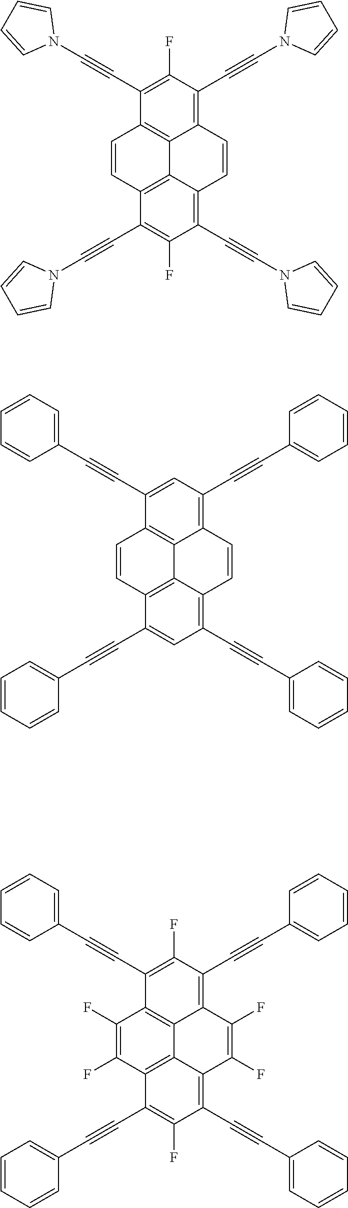

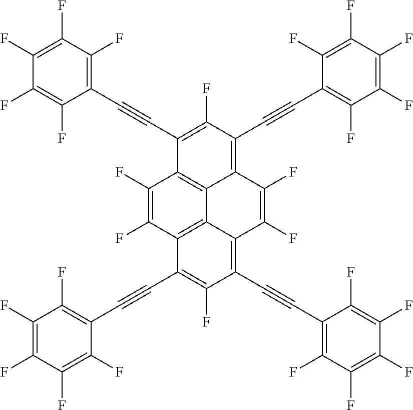 [SMILES: Fc1c(F)c(F)c(C#Cc2c(F)c(C#Cc3c(F)c(F)c(F)c(F)c3F)c3c(F)c(F)c4c(C#Cc5c(F)c(F)c(F)c(F)c5F)c(F)c(C#Cc5c(F)c(F)c(F)c(F)c5F)c5c(F)c(F)c2c3c54)c(F)c1F]

In an implementation, when the light emitting layer EML includes a second host, the second host may be, e.g., a compound of the following Compound Group 3.

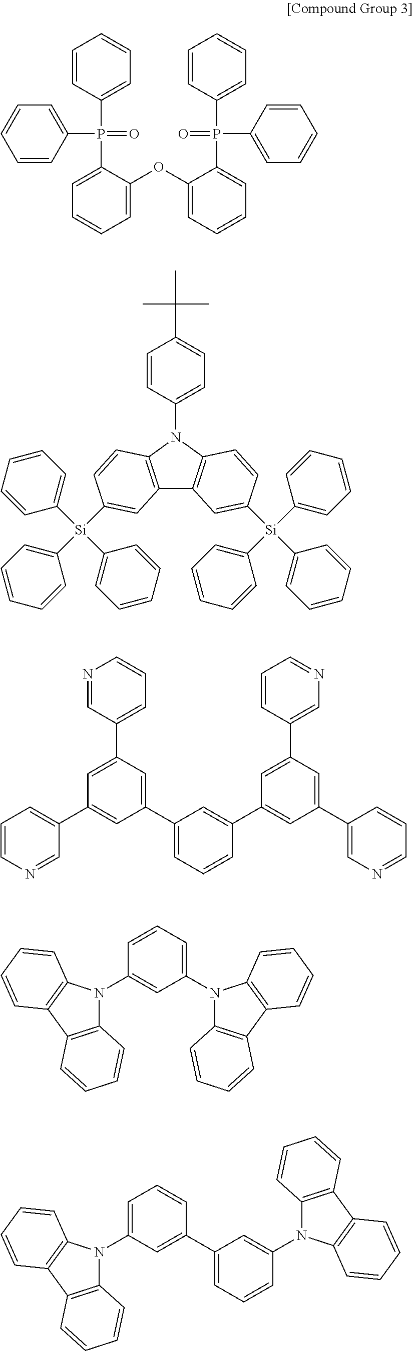 [SMILES: O=P(c1ccccc1)(c1ccccc1)c1ccccc1Oc1ccccc1P(=O)(c1ccccc1)c1ccccc1 ; CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1 ; c1cncc(-c2cc(-c3cccnc3)cc(-c3cccc(-c4cc(-c5cccnc5)cc(-c5cccnc5)c4)c3)c2)c1 ; c1cc(-n2c3ccccc3c3ccccc32)cc(-n2c3ccccc3c3ccccc32)c1 ; c1cc(-c2cccc(-n3c4ccccc4c4ccccc43)c2)cc(-n2c3ccccc3c3ccccc32)c1]

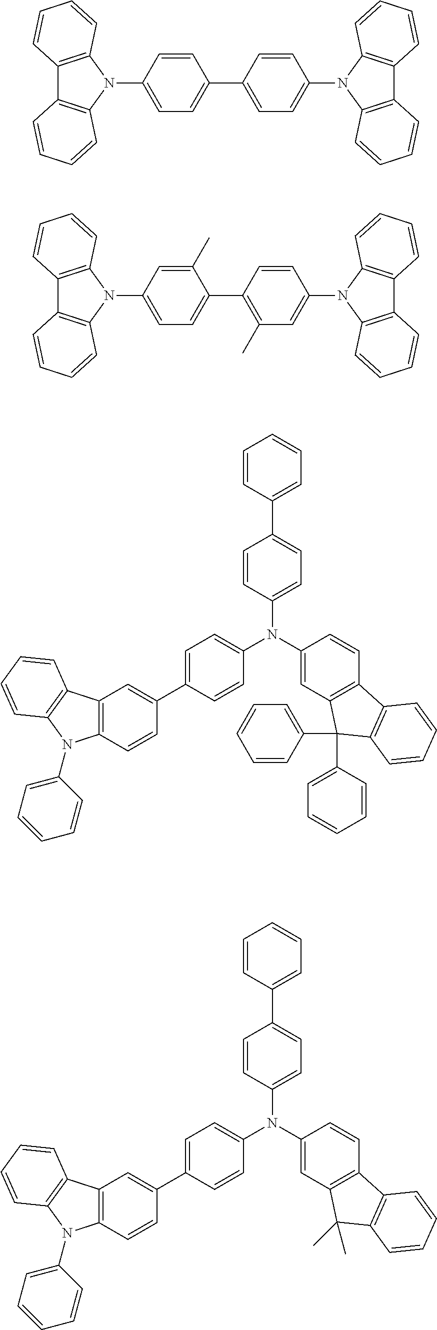 [SMILES: c1ccc2c(c1)c1ccccc1n2-c1ccc(-c2ccc(-n3c4ccccc4c4ccccc43)cc2)cc1 ; Cc1cc(-n2c3ccccc3c3ccccc32)ccc1-c1ccc(-n2c3ccccc3c3ccccc32)cc1C ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

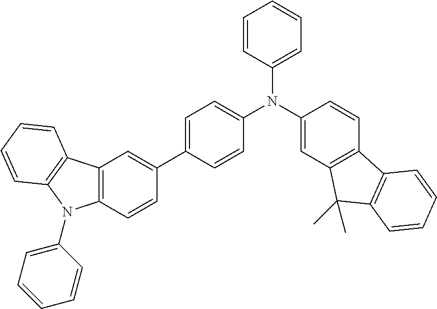 [SMILES: CC1(C)c2ccccc2-c2ccc(N(c3ccccc3)c3ccc(-c4ccc5c(c4)c4ccccc4n5-c4ccccc4)cc3)cc21]

The light emitting layer EML may be a blue light emitting layer. The light emitting layer EML may emit light having a maximum light emitting wavelength of 480 nm or less (e.g., may emit light with a maximum luminance at 480 nm or less). The light emitting layer EML may be one emitting blue light having a wavelength region of 430 nm to 480 nm.

In an implementation, the light emitting layer EML may have a thickness of, e.g., about 100 Å to about 1,000 Å.

The light emitting layer EML may further include a suitable material in addition to the first compound and the second compound if necessary.

Referring back to FIGS. 1 and 2, the electron transport region ETR may be provided on the light emitting layer EML. In an implementation, the electron transport region ETR may include, e.g., a hole blocking layer, an electron transport layer ETL, or an electron injection layer EIL.

In an implementation, the electron transport region ETR may have a single layer structure having a single layer formed of a single material, a single layer structure having a single layer formed of a plurality of different materials, or a multilayer structure having a plurality of layers formed of a plurality of different materials.

In an implementation, the electron transport region ETR may have a single layer structure having a single layer of the electron injection layer EIL or the electron transport layer ETL, or a single layer structure having a single layer formed of an electron injection material and an electron transport material. In an implementation, the electron transport region ETR may have a single layer structure having a single layer formed of a plurality of different materials, or have a structure of an electron transport layer ETL/an electron injection layer EIL, a hole blocking layer/an electron transport layer ETL/an electron injection layer EIL, sequentially laminated from the first electrode EL1.

The electron transport region ETR may be provided by various methods such as vacuum deposition, spin coating, casting, Langmuir-Blodgett (LB), inkjet printing, laser printing, and laser induced thermal imaging (LITI).

In an implementation, when the electron transport region ETR includes the electron transport layer ETL, the electron transport region ETR may include, e.g., Tris(8-hydroxyquinolinato)aluminum (Alq3), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-Tri(1-phenyl-1H-benzo[d]imidazol-2-yl)phenyl (TPBi), 2,9-Dimethyl-4,7-diphenyl-1,10-phenanthroline (BCP), 4,7-Diphenyl-1,10-phenanthroline (Bphen), 3-(4-Biphenylyl)-4-phenyl-5-tert-butylphenyl-1,2,4-triazole (TAZ), 4-(Naphthalen-1-yl)-3,5-diphenyl-4H-1,2,4-triazole (NTAZ), 2-(4-Biphenylyl)-5-(4-tert-butylphenyl)-1,3,4-oxadiazole (tBu-PBD), Bis(2-methyl-8-quinolinolato-N1,O8)-(1,1′-Biphenyl-4-olato)aluminum (BAlq), Berylliumbis(benzoquinolin-10-olate (Bebq2), 9,10-di(naphthalene-2-yl)anthracene (ADN), and a compound thereof. The thicknesses of the electron transport layers ETL may be about 100 Å to about 1,000 Å, e.g., about 150 Å to about 500 Å. When the thicknesses of the electron transport layers ETL satisfy the above-described ranges, a satisfactory electron transport characteristic may be obtained without a substantial increase in driving voltage.

In an implementation, when the electron transport region ETR includes the electron injection layer EIL, the electron transport region ETR may be formed of, e.g., a lanthanide group metal such as LiF, LiQ (Lithium quinolate), Li₂O, BaO, NaCl, CsF and Yb, or of a halogenated metal such as RbCl and RbI. The electron injection layer EIL may be formed of a mixture of an electron transport material and an insulating organo metal salt. The organic metal salt may be a material having an energy band gap of about 4 eV or greater. In an implementation, the organic metal salt may include metal acetate, metal benzoate, metal acetoacetate, metal acetylacetonate, or metal stearate. The thicknesses of the electron injection layers EIL may be about 1 Å to about 100 Å. e.g., about 3 Å to about 90 Å. When the thicknesses of the electron injection layers EIL satisfy the above-described ranges, a satisfactory electron injection characteristic may be obtained without a substantial increase in driving voltage.

The electron transport region ETR may include a hole blocking layer as mentioned above. In an implementation, the hole blocking layer may include, e.g., 2,9-dimethyl-4,7-diphenyl-1,10-phenanthroline (BCP) or 4,7-diphenyl-1,10-phenanthroline (Bphen).

The second electrode EL2 is provided on the electron transport region ETR. The second electrode EL2 may be a common electrode or a negative electrode. The second electrode EL2 may be a transmissive electrode, a transflective electrode, or a reflective electrode. When the second electrode EL2 is a transmissive electrode, the second electrode EL2 may be composed of a transparent metal oxide, e.g., indium tin oxide (ITO), indium zinc oxide (IZO), zinc oxide (ZnO), indium tin zinc oxide (ITZO), and the like.

When the second electrode EL2 is a transflective electrode or a reflective electrode, the second electrode EL2 may include, e.g., Ag, Mg, Cu, Al, Pt, Pd, Au, Ni, Nd, Ir, Cr, Li, Ca, LiF/Ca, LiF/Al, Mo, Ti, or a compound, or a mixture thereof (for example, a mixture of Ag and Mg). In an implementation, the second electrode EL2 may be of a multilayer structure including a reflective film or a transflective film, both formed of the above materials, and a transparent conductive film formed of indium tin oxide (ITO), indium zinc oxide (IZO), zinc oxide (ZnO), indium tin zinc oxide (ITZO), and the like.

In an implementation, the second electrode EL2 may be connected to an auxiliary electrode. When the second electrode EL2 is connected to the auxiliary electrode, the resistance of the second electrode EL2 may be reduced.

In the organic electroluminescence device 10, as voltage is applied to each of the first electrode EL1 and the second electrode EL1, a hole injected from the first electrode EL1 may be moved to the light emitting layer EML through the hole transport region HTR, and an electron injected from the second electrode EL2 may be moved to the light emitting layer EML through the electron transport region ETR. The electron and the hole may be recombined in the light emitting layer EML to generate an exciton, and the exciton falls to a ground state from an excited state to emit light.

When the organic electroluminescence device 10 is a top emission type, the first electrode EL1 may be a reflective electrode, and the second electrode EL1 may be a transmissive electrode or a transflective electrode. When the organic electroluminescence device 10 is a bottom emission type, the first electrode EL1 may be a transmissive electrode or a transflective electrode, and the second electrode EL2 may be a reflective electrode.

An organic electroluminescence device according to an embodiment of the present disclosure may include a light emitting layer emitting light by a fluorescent light emitting mechanism. For example, an exciton in a higher triplet excited state of a host is moved to a singlet excited state, and immediately moved to a singlet excited state of a dopant to emit fluorescent light. By reducing the time for which an exciton stays in a triplet excited state, the organic electroluminescence device according to an embodiment of the present disclosure may simultaneously realize high efficiency and long life.

Hereinafter, the embodiments will be described in more detail with reference to the following examples and comparative examples.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

Organic electroluminescence devices of the Examples and Comparative Examples were manufactured as follows.

A first electrode having a thickness of 1,500 Å was formed of ITO; a hole injection layer having a thickness of 100 Å was formed of dipyrazino[2,3-f:2′,3′-h]quinoxaline-2,3,6,7,10,11-hexacarbonitrile (HAT-CN); a hole transport layer having a thickness of 800 Å was formed of α-NPD; an electron blocking layer having a thickness of 50 Å was formed of mCP; a light emitting layer having a thickness of 200 Å was formed of x % of a dopant, y % of a first host, and z % of a second host (as tabulated in Table 1, below); a hole blocking layer having a thickness of 100 Å was formed of (bis{2-[di(phenyl)phosphino]phenyl}ether oxide (DPEPO); an electron transport layer having a thickness of 300 Å was formed of 1,3,5-Tris(1-phenyl-1H-benzimidazol-2-yl) benzene (TPBi); an electron injection layer having a thickness of 5 Å was formed of Lithium fluoride (LiF); and a second electrode having a thickness of 1,000 Å was formed of Al. Each layer was formed by vacuum deposition.

TABLE 1

| | Dopant(x %) | First host(y %) | Second host(z %) | Relative EQE | Relative life |
|---|---|---|---|---|---|
| Example 1 | D-1 (1%) | HA-1 (30%) | HB-1 (69%) | 1.0 | 1.0 |
| Example 2 | D-1 (1%) | HA-1 (30%) | HB-2 (69%) | 0.8 | 3.0 |
| Example 3 | D-1 (1%) | HA-1 (99%) | — | 0.9 | 5.0 |
| Example 4 | D-2 (1%) | HA-1 (30%) | HB-1 (69%) | 1.2 | 1.5 |
| Example 5 | D-2 (1%) | HA-1 (30%) | HB-2 (69%) | 1.0 | 3.5 |
| Example 6 | D-2 (1%) | HA-1 (99%) | — | 1.1 | 6.0 |
| Comparative | D-1 (1%) | HA-2 (30%) | HB-1 (69%) | 1.1 | 0.1 |
| Example 1 | | | | | |
| Comparative | D-1 (1%) | HA-2 (99%) | — | 0.4 | 0.05 |
| Example 2 | | | | | |

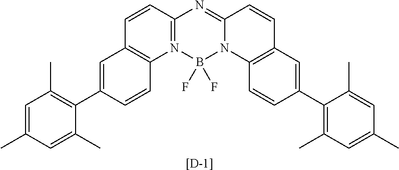

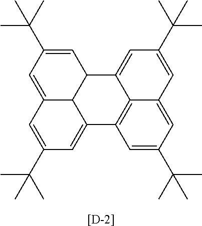

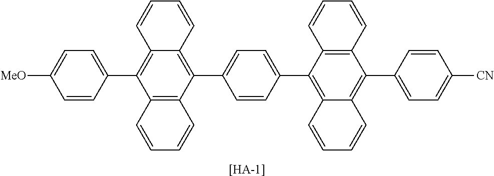

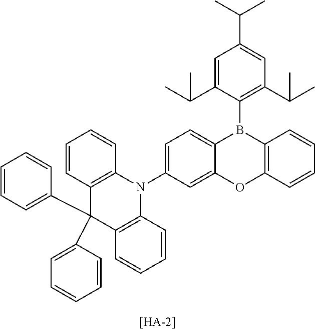

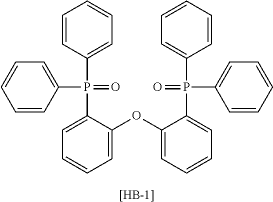

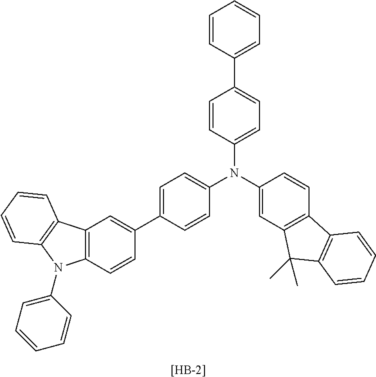

The relative EQE and the relative life respectively mean relative value when external quantum efficiency (EQE) and half luminance lifetime of Example 1 was set to 1.0.

Compound HA-1 has a full width at half maximum of about 55 nm, and Compound HA-2 has a full width at half maximum of about 65 nm.

The energy levels of the lowest singlet excited states and the lowest triplet excited states of the compounds used in Examples 1 to 6 and Comparative examples 1 to 2 are illustrated in table 2 below.

TABLE 2

| Compound | S1 (eV) | T1 (eV) |
|---|---|---|
| D-1 | 2.8 | 2.0 |
| D-2 | 2.8 | 1.8 |
| HA-1 | 2.9 | 1.7 |
| HA-2 | 2.9 | 2.8 |
| HB-1 | 4.2 | 3.4 |
| HB-2 | 3.0 | 2.3 |

Referring to Tables 1 and 2, it may be seen that Examples 1 to 6 (in which Compound HA-1 having a full width at half maximum of 60 nm or less and satisfying Formula 1 to cause reverse intersystem energy crossing from a higher triplet excited state to a singlet excited states was used as a first host) showed longer life than Comparative Examples 1 to 2 (in which Compound HA-2, a thermally activated delayed fluorescence material, was used as a first host). By shortening the time for which an exciton exists in an unstable excited state, it was possible to realize long life.

By way of summation and review, an organic electroluminescence device may be classified into a fluorescent organic electroluminescence device and a phosphorescent organic electroluminescence device according to a light emitting principle. A fluorescent organic electroluminescence device may have an external quantum efficiency thereof of less than 5%, and a phosphorescent organic electroluminescence device may have poor driving durability thereof. With this as a backdrop, a fluorescent organic electroluminescence device using triplet-triplet annihilation (TTA) in which singlet excitons are generated by the collision of triplet excitons, and a fluorescent organic electroluminescence device using thermally activated delayed fluorescence (TADF), and the like may be considered.

The embodiments may provide an organic electroluminescence device capable of simultaneously realizing the effects of high efficiency and long life.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic electroluminescence device, comprising:
a first electrode;
a hole transport region provided on the first electrode;
a light emitting layer provided on the hole transport region;
an electron transport region provided on the light emitting layer; and
a second electrode provided on the electron transport region,
wherein the light emitting layer includes a first compound satisfying Formula 1 below and a second compound satisfying Formula 2 below, and the first compound has a full width at half maximum of 60 nm or less:
V2>V1 [Formula 1]
wherein, in Formula 1,
V1 is a sum of non-radiative transition rates transitioning from an n^{th} triplet excited state to a lower order triplet excited state including the lowest triplet excited state, and
V2 is a reverse intersystem transition rate transitioning from an n^{th} triplet excited state to a singlet excited state adjacent to the n^{th} triplet excited state, where n is an integer of 2 or greater; and,
K1>1.1×K2 [Formula 2]
wherein, in Formula 2,
K1 is an energy level of a lowest singlet excited state of the second compound, and
K2 is an energy level of a lowest triplet excited state of the second compound.

2. The organic electroluminescence device as claimed in claim 1, wherein:
the light emitting layer includes a host and a dopant,
the host includes the first compound, and
the dopant includes the second compound.

3. The organic electroluminescence device as claimed in claim 2, wherein the dopant is a fluorescent dopant.

4. The organic electroluminescence device as claimed in claim 2, wherein a weight percentage of the dopant based on a total weight of the host and the dopant is 0.01 wt % to 10 wt %.

5. The organic electroluminescence device as claimed in claim 2, wherein:
the host includes a first host and a second host,
the first host is the first compound, and
an energy level of the lowest triplet excited state of the second host is higher than an energy level of the lowest singlet excited state of the first compound.

6. The organic electroluminescence device as claimed in claim 2, wherein:
the host includes a first host and a second host,
the first host is the first compound, and
an energy level of the lowest singlet excited state of the second host is lower than an energy level of the lowest singlet excited state of the first compound.

7. The organic electroluminescence device as claimed in claim 1, wherein the first compound satisfies Formula 1-1 below:
V2≥0.1×V1 [Formula 1-1]
wherein, in Formula 1-1, V1 and V2 are defined the same as those of Formula 1.

8. The organic electroluminescence device as claimed in claim 1, wherein V1 is 1×10⁹ s⁻¹ or less.
